(19) United States
(12) Patent Application Publication
(10) Pub. No.: US 2002/0009204 A1
(43) Pub. Date: Jan. 24, 2002

(54) Signal processing method and apparatus and imaging system

(76) Inventor: Shigeru Matsumura, Tokyo (JP)

Correspondence Address: MOONRAY KOJIMA, BOX 627, WILLIAMSTOWN, MA, 01267, US

(21) Appl. No.: 09/875,845

(22) Filed: Jun. 6, 2001

(30) Foreign Application Priority Data
Jun. 15, 2000 (JP) 2000-180172

(51) Int. Cl. H04B 3/20; H04B 15/00; H03G 5/00

(52) U.S. Cl. 381/98; 381/66; 381/94.2; 381/94.3

(57) ABSTRACT

With a view toward properly combining a fundamental echo with a harmonics echo according to the quality of a signal, the ratio between two frequency components of the fundamental echo is determined (704), and the ratio between two frequency components of the harmonics echo is determined (702). Further, a component ratio between a fundamental component and a harmonics component in an echo receive signal is adjusted based on these two ratios (706, 708).

### BACKGROUND OF THE INVENTION

The present invention relates to a signal processing method and apparatus, and an imaging system, and particularly to a signal processing method and apparatus for adjusting a component ratio between a fundamental component and a harmonics component in a signal obtained by receiving an echo of a wave, and an imaging system equipped with such a signal processing apparatus.

In ultrasound imaging, an image has been generated based on a signal obtained by combining a fundamental echo and a harmonics echo together. The harmonics echo is derived from non-linearity of ultrasonic propagation inside a target and generated by the progress of a wave front over a certain degree of distance. Therefore, the harmonics echo is characterized in that it is insusceptible to multiple reflection thereof by structures such as fat, and bones in the vicinity of a body surface. With attention being given to this point of view, a component ratio for the fundamental echo is decreased and a component ratio for the harmonics echo is increased with respect to an echo receive signal insofar as one or echo from a deep part is concerned in particular, thereby avoiding disturbances produced by the multiple reflection.

The harmonics echo is an essentially weak signal and increases in attenuation rate with its propagation because it is high in frequency. Therefore, the harmonics echo is easy to be reduced in CNR (contrast-to-noise ratio) due to the influence of noise. Mechanically decreasing the component ratio for the fundamental echo and increasing the component ratio for the harmonics echo according to the depth of each echo is therefore not always adequate.

### SUMMARY OF THE INVENTION

Therefore, an object of the present invention is to implement a signal processing method and apparatus for suitably combining a fundamental echo with a harmonics echo according to the quality of a signal, and an imaging system equipped with such a signal processing apparatus.

(1) The invention according to one aspect for solving the above problems is a signal processing method comprising the steps of, upon adjusting a component ratio between a fundamental component and a harmonics component in a signal obtained by receiving an echo, determining the ratio between two frequency components of a fundamental echo, determining the ration between two frequency components of a harmonics echo, and adjusting the component ratio, based on the two determined ratios.

In the invention according to this aspect, the ratios between two frequency components of a fundamental echo and a harmonics echo are respectively determined, and a component ratio between a fundamental component and a harmonics component in an echo receive signal is adjusted based on these two ratios. It is therefore possible to suitably combine a fundamental echo with a harmonics echo according to the quality of a signal.

(2) The invention according to another aspect for solving the above problems is the signal processing method described in (1), further including, upon determining the ratio between the two frequency components of the fundamental echo, quadrature-detecting the signal obtained by receiving the echo by means of two carrier signals different in frequency respectively, determining integrated values for the two quadrature-detected signals respectively, and determining the ratio between the two determined integrated values, and upon determining the ratio between the two frequency components of the harmonics echo, quadrature-detecting the signal obtained by receiving the echo by means of two carrier signals different in frequency respectively, determining integrated values for the two quadrature-detected signals, and determining the ratio between the two determined integrated values.

In the invention according to this aspect, a signal obtained by receiving an echo is quadrature-detected with two carrier signals different in frequency respectively, and integrated values are respectively determined with respect to the two quadrature-detected signals, whereby the ratio between two frequency components is determined as the ratio between those integrated values. It is therefore possible to effectively determine a frequency component ratio.

(3) The invention according to a further aspect for solving the above problems is the signal processing method described in (1), wherein the gain of a signal belonging to a frequency band for the fundamental echo and the gain of a signal belonging to a frequency band for the harmonics echo are respectively controlled with respect to the signal obtained by receiving the echo to thereby adjust the component ratio.

In the invention according to this aspect, the gain of a signal belonging to a frequency band for the fundamental echo and the gain of a signal belonging to a frequency band for the harmonics echo are respectively controlled with respect to a signal obtained by receiving an echo. Therefore, a component ratio between a fundamental component and a harmonics component in the echo receive signal can easily be adjusted.

(4) The invention according to a still further aspect for solving the above problems is the signal processing method described in any of (1) to (3), wherein the echo is an ultrasound echo.

In the invention according to this aspect, a component ratio between a fundamental component and a harmonics component can suitably be adjusted with respect to an ultrasound echo receive signal.

(5) The invention according to a still further aspect for solving the above problems is a signal processing apparatus for adjusting a component ratio between a fundamental component and a harmonics component in a signal obtained by receiving an echo, comprising first ratio calculating means for determining the ratio between two frequency components of a fundamental echo, second ratio calculating means for determining the ratio between two frequency components of a harmonics echo, and component ratio control means for adjusting the component ratio, based on the two determined ratios.

In the invention according to this aspect, the ratios between two frequency components of a fundamental echo and a harmonics echo are respectively determined, and a component ratio between a fundamental component and a harmonics component in an echo receive signal is adjusted based on these two ratios. It is therefore possible to suitably combine a fundamental echo with a harmonics echo according to the quality of a signal.

(6) The invention according to a still further aspect for solving the above problems is the signal processing apparatus described in (5), wherein the first ratio calculating means includes first quadrature-detecting means for quadrature-detecting the signal obtained by receiving the echo by means of two carrier signals different in frequency respectively, first integrating means for determining integrated values for the two quadrature-detected signals respectively, and first integrated value ratio calculating means for determining the ratio between the two determined integrated values, and the second ratio calculating means includes second quadrature-detecting means for quadrature-detecting the signal obtained by receiving the echo by means of two carrier signals different in frequency respectively, second integrating means for determining integrated values for the two quadrature-detected signals respectively, and second integrated value ratio calculating means for determining the ratio between the two determined integrated values.

In the invention according to this aspect, a signal obtained by receiving an echo is quadrature-detected with two carrier signals different in frequency respectively, and integrated values are respectively determined with respect to the two quadrature-detected signals, whereby the ratio between two frequency components is determined as the ratio between those integrated values. It is therefore possible to effectively determine a frequency component ratio.

(7) The invention according to a still further aspect for solving the above problems is the signal processing apparatus described in wherein the component ratio control means controls the gain of a signal belonging to a frequency band for the fundamental echo and the gain of a signal belonging to a frequency band for the harmonics echo with respect to the signal obtained by receiving the echo, respectively to thereby adjust the component ratio.

In the invention according to this aspect, the gain of a signal belonging to a frequency band for the fundamental echo and the gain of a signal belonging to a frequency band for the harmonics echo are respectively controlled with respect to a signal obtained by receiving an echo. Therefore, a component ratio between a fundamental component and a harmonics component in the echo receive signal can easily be adjusted.

(8) The invention according to a still further aspect for solving the above problems is the signal processing apparatus described in any of (5) to (7), wherein the echo is an ultrasound echo.

In the insertion according to this aspect, a component ratio between a fundamental component and a harmonics component can suitably be adjusted with respect to an ultrasound echo receive signal.

(9) The invention according to a still further aspect for solving the above problems is an imaging system comprising wave-sending means for transmitting a wave, wave-sensing means for transmitting a wave, receiving means for receiving an echo of the wave therein, signal processing means for adjusting a component ratio between a fundamental component and a harmonics component in a signal obtained by receiving the echo, and image generating means for generating an image, based on a signal having adjusted the component ratio, wherein the signs processing means includes first ratio calculating means for determining the ratio between two frequency components of a fundamental echo, second ratio calculating means for determining the ratio between two frequency components of a harmonics echo, and component ratio control means for adjusting the component ratio, based on the two determined ratios.

In the invention according to this aspect, the ratios between two frequency components of a fundamental echo and a harmonics echo are respectively determined, and a component ratio between a fundamental component and a harmonics component in an echo receive signal is adjusted based on these two ratios. It is therefore possible to suitably combine a fundamental echo with a harmonics echo according to the quality of a signal. An image of good quality can be generated based on such an echo receive signal.

(10) The invention according to a still further aspect for solving the above problems is the imaging system described in (9), wherein the first ratio calculating means includes first quadrature-detecting means for quadrature-detecting the signal obtained by receiving the echo by means of two carrier signals different in frequency respectively, first integrating means for determining integrated values for the two quadrature-detected signals respectively, and first integrated value ratio calculating means for determining the ratio between the two determined integrated values, and the second ratio calculating means includes second quadrature-detecting means for quadrature-detecting the signal obtained by receiving the echo by means of two carrier signals different in frequency respectively, second integrating means for determining integrated values for the two quadrature-detected signals respectively, and second integrated value ratio calculating means for determining the ratio between the two determined integrated values.

In the invention according to this aspect, a signal obtained by receiving an echo is quadrature-detected with two carrier signals different in frequency respectively, and integrated values are respectively determined with respect to the two quadrature-detected signals, whereby the ratio between two frequency components is determined as the ratio between those integrated values. It is therefore possible to effectively determine a frequency component ratio.

(11) The invention according to a still further aspect for solving the above problems is the imaging system described in (9), wherein the component ratio control means controls the gain of a signal belonging to a frequency band for the fundamental echo and the gain of a signal belonging to a frequency band for the harmonics echo with respect to the signal obtained by receiving the echo, respectively to thereby adjust the component ratio.

In the invention according to this aspect, the gain of a signal belonging to a frequency band for the fundamental echo and the gain of a signal belonging to a frequency band for the harmonics echo are respectively controlled with respect to a signal obtained by receiving an echo. Therefore, a component ratio between a fundamental component and a harmonics component in the echo receive signal can easily be adjusted.

(12) The invention according to a still further aspect for solving the above problems is the imaging system described in any of claims 9 to 11, wherein the wave is an ultrasound.

In the invention according to this aspect, a component ratio between a fundamental component and a harmonics component can suitably be adjusted with respect to an ultrasound echo receive signal. An ultrasound image of good quality can be generated based on such an ultrasound echo receive signal.

According to the present invention, a signal processing method and apparatus for properly combining a fundamental echo with a harmonics echo according to the quality or a signal, and an imaging system equipped with such a signal processing apparatus.

Further objects and advantages of the present invention will be apparent from the following description of the preferred embodiments of the invention as illustrated in the accompanying drawings.

### BRIEF DESCRIPTION OF THE DRAWINGS

FIG. 1 is a block diagram of a system showing one example of an embodiment of the present invention.

FIG. 2 is a block diagram of a transmit-receive unit employed in the system shown in FIG. 1.

FIG. 3 is a diagrammatic illustration of sound-ray scanning by the system shown in FIG. 1.

FIG. 4 is a diagrammatic illustration of sound-ray scanning by the system shown in FIG. 1.

FIG. 5 is a diagrammatic illustration of sound-ray scanning by the system shown in FIG. 1.

FIG. 6 is a block diagram of a B mode processor employed in the system shown in FIG. 1.

FIG. 7 is a block diagram of an image processor employed in the system shown in FIG. 1.

FIG. 8 is a conceptual diagram showing frequency components of an image signal.

FIG. 9 is a conceptual diagram showing frequency components or an image signal.

FIG. 10 is a block diagram of a frequency component control unit shown in FIG. 2.

FIG. 11 is a block diagram of a frequency component ratio calculating unit shown in FIG. 10.

FIG. 11 is a conceptual diagram of integration by integrating units shown in FIG. 11.

FIG. 13 is a block diagram of a frequency component ratio calculating unit shown in FIG. 10.

FIG. 14 is a graph showing one example illustrative of weights generated by a weight generating unit shown in FIG. 10.

FIG. 15 is a block diagram of a component ratio control unit shown in FIG. 10.

FIG. 16 is a graph showing one example of a filtering characteristic of a variable filtering unit shown in FIG. 15.

### DETAILED DESCRIPTION OF THE INVENTION

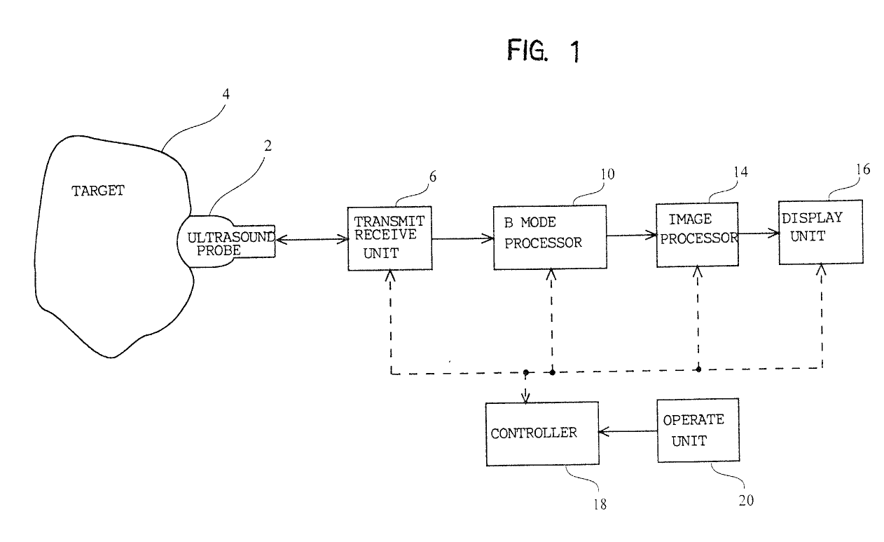

Embodiments of the present invention will hereinafter be described in detail with reference to the accompanying drawings. A block diagram of an ultrasound imaging system is shown in FIG. 1. The present system is one example of an embodiment of the present insertion. One example of an embodiment related to a system of the present invention is shown according to the configuration of the present system. One example of an embodiment related to a method of the present invention is shown according to the operation of the present system.

As shown in FIG. 1, the present system has an ultrasound probe 2. The ultrasound probe 2 has an array of a plurality of ultrasound transducers not shown in the drawing. Each of the ultrasound transducers is composed of, for example, a piezoelectric material such as PZT (titanate (Ti) lead (Pb) zirconate (Zr)) ceramic.

The ultrasound probe 2 is used so as to contact a target 4 under an operator. The ultrasound probe 2 is connected to a transmit-receive unit 6. The transmit-receive unit 6 supplies a drive signal to the ultrasound probe 2 to transmit or send an ultrasound. Further, the transmit-receive unit 6 receives an echo signal received by the ultrasound probe 2.

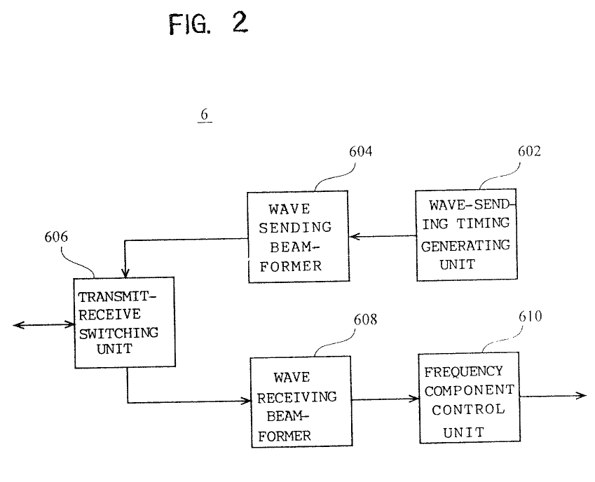

A block diagram of the transmit-receive unit 6 is shown in FIG. 2. As shown in the drawing, the transmit-receive unit 6 has a wave-sending timing generating unit 602. The wave-sending timing generating unit 602 generates a wave-sending timing signal periodically and inputs it to a wave-sending beamformer 604.

The wave-sending beamformer 604 effects beamforming on a transmitted wave. The wave-sending beamformer 604 generates a beamforming signal for forming an ultrasound beam placed in a predetermined azimuth or bearing, based on the wave-sending timing signal. The beamforming signal comprises a plurality of drive signals each supplied with a time difference corresponding to the azimuth. The beamforming is controlled by a controller 18 to be described later.

The signal outputted from the wave-sending beamformer 604 is inputted to the ultrasound transducer array through a transmitter-receive switching unit 606. In the ultrasound transducer array, the plurality of ultrasound transducers each constituting a wave-sending aperture respectively generate ultrasounds each having a phase difference corresponding to the difference in time between the drive signals. An ultrasound beam extending along a sound ray placed in a predetermined azimuth is formed according to a wave front combination of those ultrasounds. A portion, which comprises the wave-sending beamformer 604, the transmit-receive switching unit 606 and the ultrasound probe 2, is one example of an embodiment of wave-sending means employed in the present invention.

A wave-receiving beamformer 608 is connected to the transmit-receive switching unit 606. The transmit-receive switching unit 606 inputs a plurality of echo signals received by their corresponding wave-receiving apertures in the ultrasound transducer array to the wave-receiving beamformer 608.

The wave-receiving beamformer 608 serves so as to effect beamforming on a received wave corresponding to a sound ray of a transmitted wave. The wave-receiving beamformer 608 supplies time differences to a plurality of received echoes to adjust phases and then adds them together to form an echo receive signal along a sound ray placed in a predetermined azimuth.

For instance, a digital-beamformer is used as the wave-receiving beamformer 608. Thus, an echo receive signal formed by bringing an RF (radio frequency) signal into digital form is obtained.

The beamforming on the received wave is controlled by the controller to be described later. A portion, which comprises the ultrasound probe 2, the transmit-receive switching unit 606 and the wave-receiving beamformer 608, is one example of an embodiment of receiving means employed in the present invention.

The output signal of the wave-receiving beamformer 608, i.e., one echo receive signal corresponding to one sound ray is inputted to a frequency component control unit 610. The frequency component control unit 610 serves so as to control a composition or component ratio between a fundamental echo component and a harmonics echo component in the echo receive signal corresponding to one sound ray. Such a frequency component control unit 610 is implemented by a DSP (Digital Signal Processor) or the like, for example. The frequency component control unit 610 will be explained anew later.

The frequency component control unit 610 is one example of an embodiment of a signal processing apparatus employed in the present invention. One example of an embodiment related to the system of the present invention is shown according to the present apparatus. One example of an embodiment related to a method of the present invention is shown according to the operation of the present apparatus. The frequency component control unit 610 is also one example of signal processing means employed in the present invention.

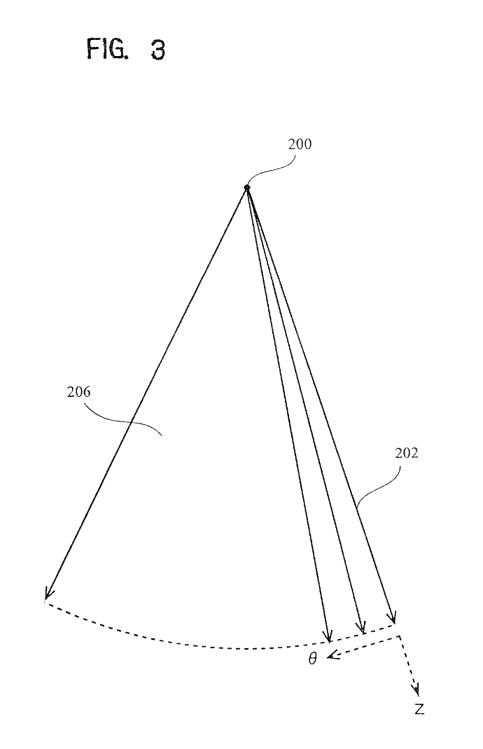

The transmit-receive unit 6 scans the inside of the target 4 in sound-ray sequential form. The sound-ray sequential scanning is carried out as shown in FIG. 3 by way of example. Namely, the transmit-receive unit 6 scans a sectorial two-dimensional area 206 in a θ direction through the use of sound rays 202 extending in a z direction from a radiant point 200, i.e., performs so-called sector scan.

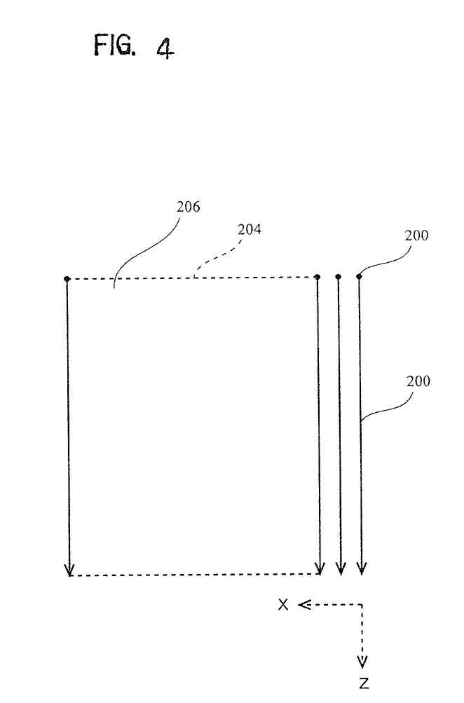

When wave-sending and -receiving apertures are formed using part of the ultrasound transducer array, the apertures are successively moved along the array to thereby allow such scanning as shown in FIG. 4, for example. Namely, sound rays 202 emitted in a z direction from radiant points 200 are parallel translated or moved along a linear trajectory 204 to thereby scan a rectangular two-dimensional area 206 in an x direction, i.e., perform so-called linear scan.

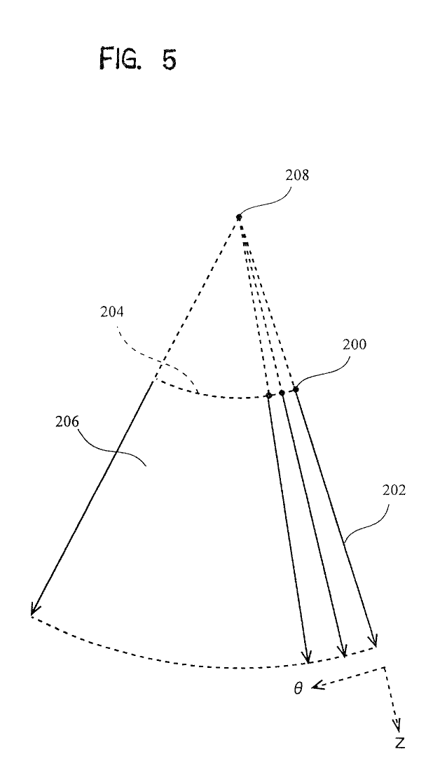

Incidentally, when the ultrasound transducer array is a so-called convex array formed along a circular arc which extends out in an ultrasound sending direction, radiant points 200 for sound rays 212 are moved along an arc trajectory 204 according to sound-ray scan similar to the linear scan to thereby scan a sectorial two-dimensional area 206 in a θ direction as shown in FIG. 5 by way of example, whereby it is needless to say that so-called convex scan can be carried out.

The transmit-receive unit 6 is connected to a B mode processor 10. An echo receive signal set for each sound ray, which is outputted from the transmit-receive unit 6, is inputted to the B mode processor 10.

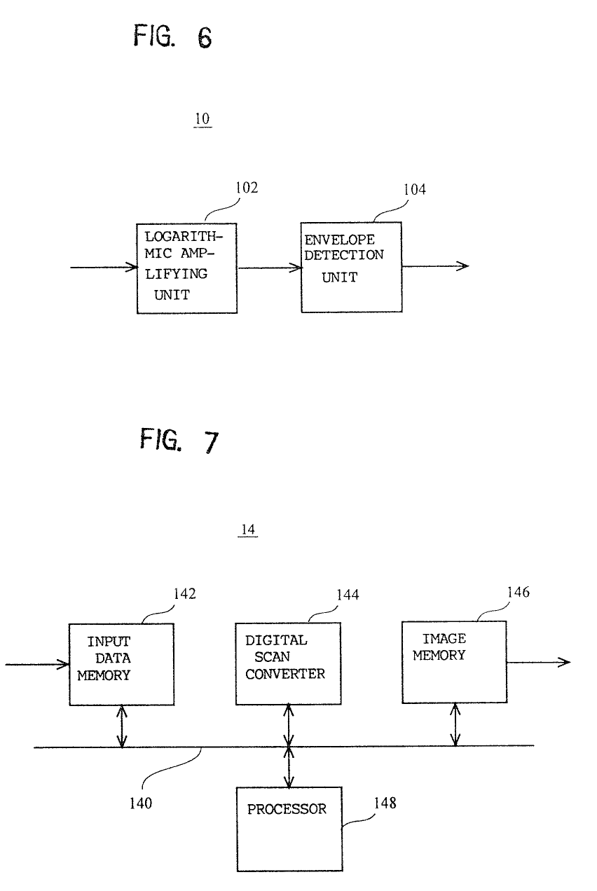

The B mode processor 10 forms B-mode image data. As shown in FIG. 6, the B mode processor 10 has a logarithmic amplifying unit 102 and an envelope detection unit 104. In the B mode processor 10, the logarithmic amplifying unit 102 logarithmically amplifies the echo receive signal and the envelope detection unit 104 detects an envelope thereof to obtain a signal indicative of the intensity of an echo at each reflecting point on a sound ray, i.e., an A scope signal, thereby forming B-mode image data with respective instantaneous amplitudes of the A scope signal as luminance values respectively.

The B mode processor 10 is connected to an image processor 14. The image processor 14 generates B-mode images, based on the data inputted from the B mode processor 10, respectively. A portion, which comprises the B mode processor 10 and the image processor 14, is one example of an embodiment of image generating means employed in the present invention.

As shown in FIG. 7, the image processor 14 is equipped with an input data memory 142, a digital scan converter 144, an image memory 146 and a processor 148 connected to one another by a bus 140.

The B-mode image data inputted from the B mode processor 10 for every sound ray is respectively stored in the input data memory 142. The data stored in the input data memory 142 is scanned and converted by digital scan converter 144, followed by storage thereof in the image memory 146. The processor 148 effects predetermined data processing on the data stored in the input data memory 142 and the image memory 146.

A display unit 16 is connected to the image processor 14. The display unit 16 is supplied with an image signal from the image processor 14 and displays an image, based on the image signal. The display unit 16 comprises a graphics display or the like capable of displaying a color image thereon.

The controller 18 is connected to the transmit-receive unit 6, B-mode processor 10, image processor 14 and display unit 16 referred to above. The controller 18 supplies a control signal to their respective portions to control their operations. Various notification signals are inputted to the controller 18 from respective portions to be uncontrolled.

A B-mode operation is executed under the control of the controller 18. An operation or control unit 20 is connected to the controller 18. The operation unit 20 is operated by an operator and serves so as to input suitable commands and information to the controller 18. The operation unit 20 comprises a control panel provided with, for example, a keyboard, a pointing comprises a control panel provided with, for example, a keyboard, a pointing device and other operation devices.

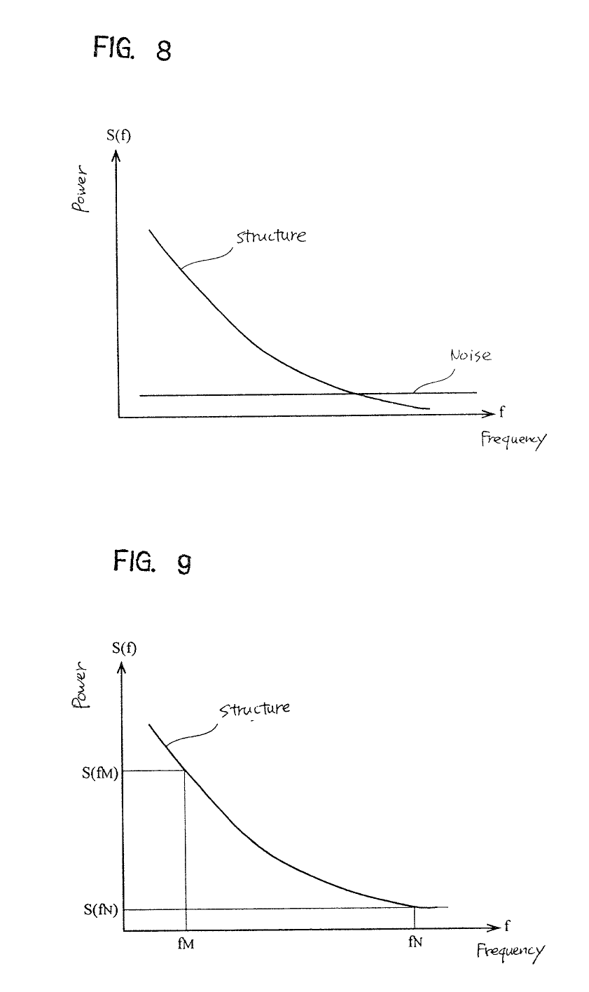

The frequency component control unit 610 will be described. The general property of an image signal will be explained as a preliminary description prior to its description. Since an image normally includes an edge structure, the power of a frequency component of the image signal is inversely proportional to the frequency as conceptually indicated in FIG. 8. On the other hand, since noise bears no relation to the structure, the power thereof does not depend on the frequency and indicates a substantially uniform frequency distribution as indicated in the same drawing.

Thus, the distribution of a frequency component or an image signal including noise is given as indicated in FIG. 9. Such a signal can be represented by the following equation.

[Equation 1]

$$S ( f ) = A \cdot \frac{1}{f} + C \qquad ( 1 )$$

where A, C: constants

Powers S(f_{M}) and S(f_{N}) with respect to two frequencies f_{M} and f_{N} of this signal are measured and the following simultaneous equations are solved.

[Equation 2]

$$S ( {f}_{w} ) = A \cdot \frac{1}{{f}_{M}} + C \qquad ( 2 )$$

[Equation 3]

$$S ( {f}_{v} ) = A \cdot \frac{1}{{f}_{N}} + C \qquad ( 3 )$$

whereby the values of constants A and C can be obtained.

A indicates a constant related to the net signal, and C indicates a constant equivalent to noise.

When the ratio between the two is taken as follows:

[Equation 4]

$$\frac{A}{C}$$

an image in which this value is large, is high in CNR (contrast-to-noise ratio) and hence it can be represented as a standard or guide of CNR.

Incidentally, the following ratio between the powers or absolute values of the two frequency components is used as an alternative to the ratio between A and C from a practical standpoint as given from the following equation.

[Equation 5]

$$\frac{\vert S ( {f}_{u} ) \vert}{\vert S ( {f}_{v} ) \vert}$$

It is convenient to represent it as the guide of CNR.

In this case, the frequency f_{M} is selected from a frequency range in which a signal indicates large frequency dependence, and the frequency f_{N} is selected from a frequency range in which the signal does not substantially indicate frequency dependence. Since the frequency range indicative of the large frequency dependence and the frequency range substantially indicating no frequency dependence are known in advance, the frequencies f_{M} and f_{N} can be defined properly in advance.

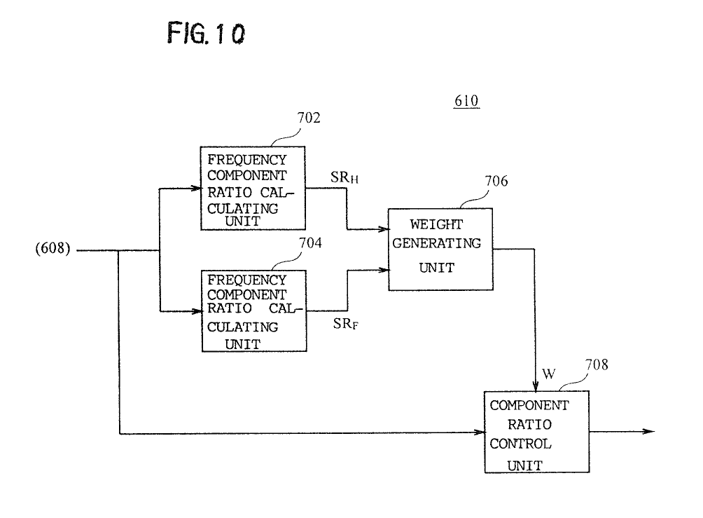

A more detailed block diagram of the frequency component control unit 610 is shown in FIG. 10. As shown in the same drawing, the frequency component control unit 610 has frequency component ratio calculating units 702 and 704.

The frequency component ratio calculating unit 702 calculates the ratio between absolute values of two frequency components in a harmonics echo, based on an echo receive signal inputted from the wave-receiving beamformer 608. Namely, it is given as follows:

[Equation 6]

$${SR}_{H} = \frac{\vert S ( {f}_{HM} ) \vert}{\vert S ( {f}_{HN} ) \vert} \qquad ( 4 )$$

This SR_{N} defined as a guide of CNR of the harmonics echo. Eor convenience, SR_{H} is also called CNR of the harmonics echo below.

The frequencies of the two frequency components are given as f_{HM} and f_{HN}. The frequency f_{HM} is a frequency selected from a frequency range in which an image signal constituting a harmonics image indicates large frequency dependence. The frequency f_{HN} is a frequency selected from a frequency range in which the image signal constituting the harmonics echo image does not substantially indicate frequency dependence. The frequency component ratio calculating unit 702 is one example of an embodiment of second ratio calculating means employed in the present invention.

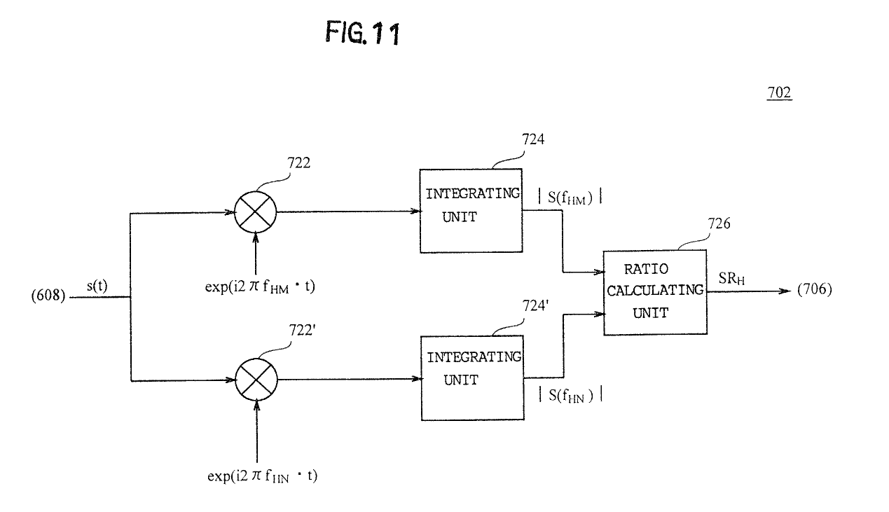

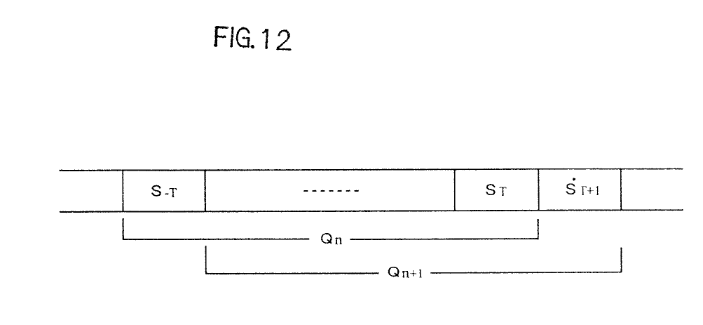

A more detailed block diagram of the frequency component ratio calculating unit 702 is shown in FIG. 11. As shown in the same drawing, the frequency component ratio calculating unit 702 multiplies an echo receive signal s(t) by signals given by the following equations through the use of multiplying units 722 and 722′.

[Equation 7]

exp(i2πƒ_{HM}·t)

and

[Equation 8]

exp(i2πƒ_{HN}·t)

This is equivalent to the fact that the echo receive signal s(t) is quadrature-detected based on carrier signals of frequencies f_{HM} and f_{HN} respectively. A portion, which comprises the multiplying units 722 and 722′, is one example of an embodiment of second quadrature detecting means employed in the present invention.

Signals obtained by quadrature-detecting the echo receive signal s(t) with the frequencies f_{HM} and f_{HN} respectively are integrated by integrating units 724 and 724′ respectively.

Their integral operations are respectively carried out according to the following equation.

[Equation 9]

$${S}_{M} = {\int }_{- {T}_{HM}}^{{T}_{HM}} s ( t ) exp ( i2 π {f}_{HM} \cdot t ) ⅆ t \qquad ( 5 )$$

[Equation 10]

$${S}_{N} = {\int }_{- {T}_{HN}}^{{T}_{HN}} s ( t ) exp ( i2 π {f}_{HN} \cdot t ) ⅆ t \qquad ( 6 )$$

Both of the above equations indicate finite Fourier (Fourier) transforms. Repetition cycles of the finite Fourier transforms are respectively given as T_{HM} and T_{HN}. T_{HM} and T_{HN} respectively indicate cycles of quadrature-detected carrier signals. A portion, which comprises the integrating units 724 and 724′, is one example of an embodiment of second integrating means employed in the present invention.

The integration of each of the integrating units 724 and 724′ is carried out according to the following procedure. The integral operation actually corresponds to summation or integral calculation of discrete data. The integration of a certain one interval (cycle) is given by the following equation.

[Equation 11]

$$Qn = {\sum }_{i = - 1}^{l} Si \qquad ( 7 )$$

If it is conceptually illustrated, it is then represented as shown in FIG. 12. One obtained by integrating data of S_{-T} to S_{T} of a sequential data string results in an integrated value Qn corresponding to one interval.

An integrated value Qn+1 corresponding to the next interval is determined by subtracting S_{-T} of the data used upon the calculation of Qn from Qn and adding new data S_{T+1} to the result of subtraction. Namely, it is represented as follows:

[Equation 12]

Qn+1=Qn−S_{-T}+S_{T+1} (8)

Owing to the sequential execution of such a calculation, finite Fourier transformation about an infinitely continuous input signal s(t) can be performed without causing discontinuity.

The integrating units 724 and 724′ also determine the absolute values (powers) of complex number data with respect to the above result of calculation. Since no phase information is required owing to the determination of the absolute values, it is not necessary to adjust the phases of the carrier signals every intervals for the finite Fourier transformation upon quadrature detection by the multiplying units 722 and 722′.

According to the above data processing, the following are respectively obtained as signals outputted from the integrating units 724 and 724′.

[Equation 13]

|S(ƒ_{HM})|

and

[Equation 14]

|S(ƒ_{HN})|

These signals are inputted to a ratio calculating unit 726. The ratio calculating unit 726 calculates the ratio between the input signals as given by the following equation and outputs it therefrom.

[Equation 15]

$${SR}_{H} = \frac{\vert S ( {f}_{HM} ) \vert}{\vert S ( {f}_{HN} ) \vert}$$

The ratio calculating unit 726 is one example of an embodiment of second integrated value ratio calculating means employed in the present invention.

Referring back to FIG. 10, the frequency component ratio calculating unit 704 calculates the ratio between two frequency components in a fundamental echo, i.e., the ratio given by the following equation, based on the echo receive signal inputted from the wave-receiving beamformer 608.

[Equation 16]

$${SR}_{Γ} = \frac{\vert S ( {f}_{F M} ) \vert}{\vert S ( {F}_{FN} ) \vert} \qquad ( 9 )$$

This SR_{F} is defined as a guide for CNR of the fundamental echo. The SR_{F} is also called CNR of the fundamental echo below for inconvenience.

The frequencies of the two frequency components are given as f_{FM} and f_{FN}. The frequency f_{FM} is a frequency selected from a frequency range in which an image signal constituting a fundamental echo image indicates large frequency dependence. The frequency f_{FN} is a frequency selected from a frequency range in which the image signal constituting the fundamental echo image does not substantially indicate frequency dependence. The frequency component ratio calculating unit 704 is one example of an embodiment of first ratio calculating means employed in the present invention.

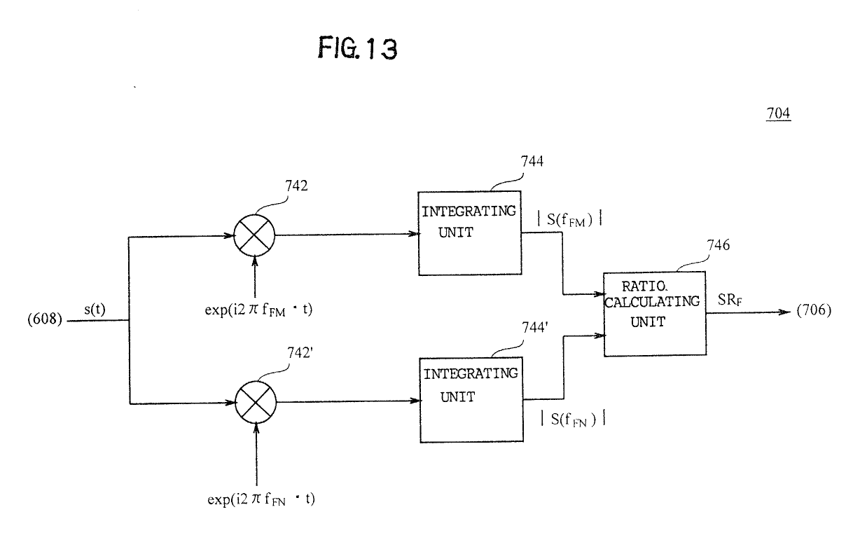

A more detailed block diagram of the frequency component ratio calculating unit 704 is shown in FIG. 13. As shown in the same drawing, the frequency component ratio calculating unit 704 has a configuration similar to the frequency component ratio calculating unit 702 shown in FIG. 11. The frequency component ratio calculating unit 704 is different from the frequency component ratio calculating unit 702 only in that the frequencies of the carrier signals used for quadrature detection are respectively given as f_{FM} and f_{FN}.

A portion, which comprises multiplying units 742 and 742′, is one example of an embodiment of the first quadrature detecting means employed in the present invention. A portion, which comprises integrating units 744 and 744′, is one example of an embodiment of the first integrating means employed in the present invention. A ratio calculating unit 746 is one example of an embodiment of first integrated value ratio calculating means employed in the present invention.

The frequency component ratio calculating means 704 determines the ratio between the two frequency components expressed in the equation (9) as to the fundamental echo according to the operation similar to the frequency component ratio calculating unit 702.

The SR_{H} and SR_{F} respectively determined by the frequency component ratio calculating units 702 and 704 are inputted to a weight generating unit 706. The weight generating unit 706 generates a weight signal W, based on the two input signals. The weight generating unit 706 comprises, for example, a lookup table (LUT) or the like.

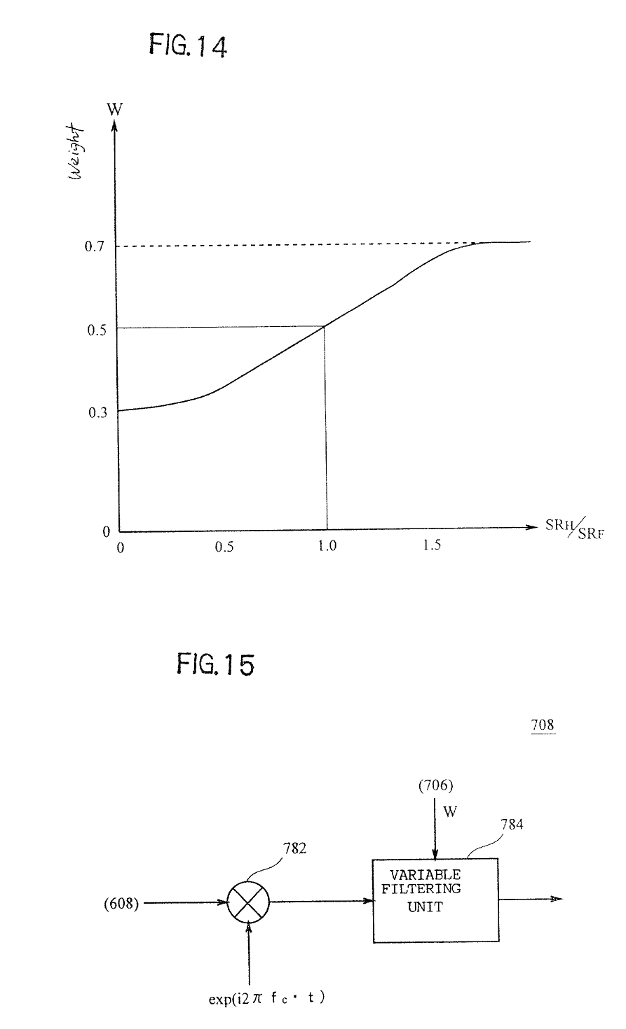

The weight generating unit 706 generates a weight W indicative of a function of the ratio between SR_{H} and SR_{F} as shown in FIG. 14 by way of example. The weight W is a weight used for the harmonics echo. A weight used for the fundamental echo is given as 1−W.

When SR_{H}/SR_{F}=1, the weight for the harmonics echo is defined as W =0.5. Thus, when CNR of the harmonics echo and CNR of the fundamental echo are equal to each other, the weights are assigned to the harmonics echo and the fundamental echo 0.5 by 0.5 to even up the weights of the two.

Since the equality of CNR of the harmonics echo to CNR of the fundamental echo means that there is no difference in quality between both signals, the equalization of the weights between the two is reasonable.

W linearly increases on the whole in a range of SR_{H}/SR_{F}=1 to 1.5, whereas W gradually approaches 0.7 in a range in which SR_{H}/SR_{F} exceeds 1.5. Thus, as CNR of the harmonics echo gets better in degree than CNR of the fundamental echo, the weight for the harmonics echo is increased and the weight for the fundamental echo is decreased. Such an increase in the weight of one good in quality is reasonable. However, the maximum value of the weight for the harmonics echo is given as 0.7, and the minimum value of the weight for the fundamental echo is given as 0.3.

In a range in which SR_{H}/SR_{F} ranges from 1 to 0.3, W decreases linearly on the whole. In a range in which SR_{H}/SR_{F} falls below 0.3, W gradually approaches 0.3. Thus, as CNR of the harmonics echo gets worse in degree than CNR of the fundamental echo, the weight for the harmonics echo is decreased and the weight for the fundamental echo is increased. Such a decrease in the weight of one bad in quality is reasonable. However, the minimum value of the weight for the harmonics echo is given as 0.3, and the maximum value of the weight for the fundamental echo is given as 0.7.

The weight signal W is supplied to a component ratio adjustment or control unit 708 as a control signal. The component ratio control unit 708 adjusts a component ratio between the fundamental echo and the harmonics echo in the echo receive signal inputted from the beamformer 608, based on the control signal. A portion, which comprises the weight generating unit 706 and the component ratio control unit 708, is one example of an embodiment of component ratio control means employed in the present invention.

A more detailed block diagram of the component ratio control unit 708 is shown in FIG. 15. As shown in the same drawing, the component ratio control unit 708 quadrature-detects the echo receive signal through the use of a multiplying unit 782. The frequency of a carrier signal is given as fc. The frequency fc is caused to coincide with a central frequency of a sending ultrasound, for example. Thus, the echo receive signal is converted to a base band signal.

The echo receive signal subjected to the quadrature detection is inputted no a variable filtering unit 784. A filtering characteristic of the variable filtering unit 784 is controlled by the weight signal W.

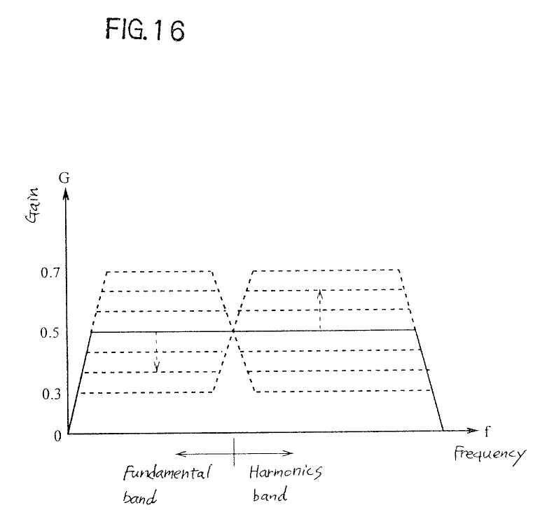

The filtering characteristic of the variable filtering unit 784 is typically shown in FIG. 16. As shown in the same drawing, the gain of the variable filtering unit 784 results in 0.5 through a harmonics band or bandwidth and a fundamental band or bandwidth when the weight W is 0.5. In a signal outputted from the variable filtering unit 784 having such a filtering characteristic, the component ratio between the harmonics echo and the fundamental echo remains unchanged as compared with that for the input signal. Namely, an output signal is obtained which has the same component ratio between the harmonics echo and fundamental echo as that for the input signal.

When the weight W becomes greater than 0.5, correspondingly the gain of the harmonics band increases and the gain of the fundamental band decreases, as indicated by arrows. Thus, an output signal is obtained wherein the component ratio for the harmonics echo is increased and the component ratio for the fundamental echo is decreased as compared with the input signal. In the ultimate sense, the gain of the harmonics band increases to 0.7 and the gain of the fundamental band is reduced to 0.3.

When the weight W becomes smaller than 0.5, correspondingly the gain of the harmonics band decreases and the gain of the fundamental band increases contrary to arrows. Thus, an output signal is obtained wherein the component ratio for the harmonics echo is decreased and the component ratio for the fundamental echo is increased as compared with the input signal. In the ultimate sense, the gain of the harmonics band is reduced to 0.3 and the gain of the fundamental band increases to 0.7.

A description will be made of ultrasound imaging executed by the present system. The operator brings the ultrasound probe 2 into contact with the target 4 in a desired place and manipulates the operation unit 20 to perform B-mode shooting or imaging. Thus, the B-mode imaging is done under the control of the controller 18.

The transmit-receive unit 6 scans the inside of the target 4 in sound-ray sequential form through the ultrasound probe 2 and receives echoes thereof point by point. With respect to the echo receive signal corresponding to each sound ray, a component ratio between a harmonics echo and a fundamental echo is dynamically adjusted owing to the above-described action or frequency component control unit 610 according to the qualities of the harmonics echo and fundamental echo.

The B mode processor 10 logarithmically amplifies the echo receive signal inputted from the transmit-receive unit 6 through the use of the logarithmic amplifying unit 102 and detects an envelop thereof through the use of the envelope detection unit 104 to obtain an A scope signal, thereby forming B-mode image data for each sound ray, based on the A scope signal.

The image processor 14 stores the B-mode image data set for every sound ray, which is inputted from the B mode processor 10, in the input data memory 142. Thus, a sound-ray data space about the B-mode image data is formed within the input data memory 142.

The processor 148 scans and converts the B-mode image data of the input data memory 142 through the use of the digital scan converter 144 respectively and writes the same in the image memory 148. A B-mode image indicates a tomogram of an in-vivo tissue on a sound-ray scanning plane by each echo. This image is displayed on the display unit 16 and is used for desired purposes such as a diagnosis.

Since the component ratio between the harmonics echo and the fundamental echo in the echo receive signal is dynamically adjusted according to the signal quality, an image of good quality can be obtained.

While the above embodiment has been described by the example in which the image is generated using the ultrasound echoes, the wave used for imaging is not limited to the ultrasound. Even when other waves such as a seismic wave are used, a similar effect can be achieved by the present invention.

Many widely different embodiments of the invention may be configured without departing from the spirit and the scope of the present invention. It should be understood that the present invention is not limited to the specific embodiments described in the specification, except as claimed in the appended claims.

1. A signal processing method comprising the steps of, upon adjusting a component ratio between a fundamental component and a harmonics component in a signal obtained by receiving an echo:
determining the ratio between two frequency components of a fundamental echo;
determining the ratio between two frequency components of a harmonics echo; and
adjusting the component ratio, based on said two determined ratios.

2. The signal processing method according to claim 1, further including, upon determining the ratio between the two frequency components of the fundamental echo,
quadrature-detecting the signal obtained by receiving the echo by means of two carrier signals different in frequency respectively,
determining integrated values for said two quadrature-detected signals respectively, and
determining the ratio between said two determined integrated values, and
upon determining the ratio between the two frequency component of the harmonics echo,
quadrature-detecting the signal obtained by receiving the echo by means of two carrier signals different in frequency respectively,
determining integrated values for said two quadrature-detected signals, and
determining the ratio between said two determined integrated values.

3. The signal processing method according to claim 1, wherein the gain of a signal belonging to a frequency band for the fundamental echo and the gain of a signal belonging to a frequency band for the harmonics echo are respectively controlled with respect to the signal obtained by receiving the echo to thereby adjust the component ratio.

4. The signal processing method according to claim 1, wherein said echo is an ultrasound echo.

5. A signal processing apparatus for adjusting a component ratio between a fundamental component and a harmonics component in a signal obtained by receiving an echo, comprising:
a first ratio calculating device for determining the ratio between two frequency components of a fundamental echo;
a second ratio calculating device for determining the ratio between two frequency components of a harmonics echo; and
a component ratio control device for adjusting the component ratio, based on the two determined ratios.

6. The signal processing apparatus according to claim 5, wherein said first ratio calculating device includes,
a first quadrature-detecting device for quadrature-detecting the signal obtained by receiving the echo by device of two carrier signals different in frequency respectively,
a first integrating device for determining integrated values for the two quadrature-detected signals respectively, and
a first integrated value ratio calculating device for determining the ratio between the two determined integrated values, and
said second ratio calculating device includes,
a second quadrature-detecting device for quadrature-detecting the signal obtained by receiving the echo by device of two carrier signals different in frequency respectively,
a second integrating device for determining integrated values for the two quadrature-detected signals respectively, and
a second integrated value ratio calculating device for determining the ratio between the two determined integrated values.

7. The signal processing apparatus according to claim 5, wherein the component ratio control device controls the gain of a signal belonging to a frequency band for the fundamental echo and the gain of a signal belonging to a frequency band for the harmonics echo with respect to the signal obtained by receiving the echo, respectively to thereby adjust the component ratio.

8. The signal processing apparatus according to claim 5, wherein said echo is an ultrasound echo.

9. An imaging system comprising:
a wave-sending device for transmitting a wave;
a receiving device for receiving an echo of the wave therein;
a signal processing device for adjusting a component ratio between a fundamental component and a harmonics component in a signal obtained by receiving the echo; and
an image generating device for generating an image, based on a signal having adjusted the component ratio,
wherein said signal processing device includes,
a first ratio calculating device for determining the ratio between two frequency components of a fundamental echo;
a second ratio calculating device for determining the ratio between two frequency components of a harmonics echo; and
a component ratio control device for determining the ratio between based on the two determined ratios.

10. The imaging system according to claim 9, wherein said first ratio calculating device includes,
a first quadrature-detecting device for quadrature-detecting the signal obtained by receiving the echo by device of two carrier signals different in frequency respectively,
a first integrating device for determining integrated values for the two quadrature-detected signals respectively, and
first integrated value ratio calculating device for determining the ratio between the two determined integrated values, and
said second ratio calculating device includes,
a second quadrature-detecting device for quadrature-detecting the signal obtained by receiving the echo by device of two carrier signals different in frequency respectively,
a second integrating device for determining integrated values for the two quadrature-detected signals respectively, and
a second integrated value ratio calculating device for determining the ratio between the two determined integrated values.

11. The imaging system according to claim 9, wherein said component ratio control device controls the gain of a signal belonging to a frequency band for the fundamental echo and the pair of a signal belonging to a frequency band for the harmonics echo with respect to the signal obtained by receiving the echo, respectively to thereby adjust the component ratio.

12. The imaging system according to claim 9, wherein said wave as an ultrasound.
